(19) United States
(12) Patent Application Publication
(10) Pub. No.: US 2026/0362937 A1
(43) Pub. Date: Nov. 12, 2026

(54) DISPLAY DEVICE

(71) Applicant: LG Display Co., Ltd., Seoul (KR)

(72) Inventor: Ji-Su HAN, Paju-si (KR)

(21) Appl. No.: 19/656,108

(22) Filed: Apr. 23, 2026

(30) Foreign Application Priority Data
May 9, 2025 (KR) 10-2025-0060157

(51) Int. Cl. H10K 59/50; G02F 1/13357; H10K 59/122; H10K 59/80

(52) U.S. Cl. CPC H10K 59/50; G02F 1/133603; H10K 59/122; H10K 59/8791; G02F 2203/02

(57) ABSTRACT

A display device includes a bank layer disposed an outside of a light emitting diode and includes a cholesteric liquid crystal. Incident light in a viewing angle direction from the light emitting diode to the bank layer, optionally, incident light in a front direction to the bank layer are converted into reflection light in a visible light wavelength band while passing through the cholesteric liquid crystal, emitted and collected to a display surface. The display device with beneficial luminance and light extraction efficiency and minimized color change rate is implemented.

### CROSS REFERENCE TO RELATED APPLICATION

Pursuant to 35 U.S.C. § 119(a), this application claims the benefit of an earlier filing date and right of priority to Korean Patent Application No. 10-2025-0060157, filed on May 9, 2025, which is hereby incorporated by reference for all purposes as if fully set forth herein.

### TECHNICAL FIELD

The present disclosure relates generally to a display device.

### BACKGROUND

Various display devices for displaying images in a TV, a monitor, a smart phone, a tablet PC and a notebook computer have been utilized. The display devices include a display panel having multiple light emitting elements or liquid crystals for implementing images and transistors for controlling each light emitting element or liquid crystal so that the display devices can display desired images through the multiple light emitting element or the liquid crystals.

Technologies for a light emitting display device including a light emitting diode as one of the display devices have been developed rapidly. Light emitting display devices may be categorized as an organic light emitting display device using organic luminescent materials and an inorganic light emitting display device using inorganic luminescent materials.

There is a need to improve luminance and light extraction efficiency of light emitted from the light emitting diode and to implement uniform visibility in the display device. Recently, extensive research and development efforts have been performed to improve reliability and image quality of the display devices.

The above information disclosed in this Background section is only for understanding of the background of the inventive concepts, and, therefore, it may contain information that does not constitute prior art.

### SUMMARY

A display device according to an implementation includes a substrate having an emission area and a non-emission area; a light emitting diode disposed on the substrate in the emission area; and a bank layer disposed in the non-emission area outside of the light emitting diode, wherein the bank layer includes a first side facing the light emitting diode, wherein the first side of the bank layer has a cross-sections inclined toward the light emitting diode, and wherein the bank layer includes a cholesteric liquid crystal.

The cholesteric liquid crystal may reflect light that is incident on the bank layer with a viewing angle.

The cholesteric liquid crystal may reflect light incident on the bank layer with a viewing angle and light that is incident on a front direction of the bank layer.

The cholesteric liquid crystal may reflect visible light having a wavelength greater than or equal to a yellow wavelength band with respect to incident light in a viewing angle direction based on a spiral axis of a liquid crystal molecule.

As an example, the cholesteric liquid crystal may reflect visible light having a wavelength of a red wavelength band with respect to incident light in a viewing angle direction based on a spiral axis of a liquid crystal molecule.

The cholesteric liquid crystal reflects near-infrared light, for example, near-infrared light having a wavelength band between 800 nm and 100 nm, with respect to front incident light parallel to a spiral axis of a liquid crystal molecule.

The cholesteric liquid crystal may be oriented in a random direction.

The bank layer may include a matrix, and the matrix may comprise a matrix resin for dispersing the cholesteric liquid crystal.

The cholesteric liquid crystal may be oriented within a droplet dispersed in the matrix resin.

The cholesteric liquid crystal may be transparent in a front direction and may be red in a viewing angle direction.

In one implementation, the light emitting diode may comprise a first electrode disposed on the substrate, a second electrode facing the first electrode and an emissive layer disposed between the first electrode and the second electrode, and each of the emissive layer and the second electrode may be disposed to extend along an upper surface of the bank layer.

The bank layer may further include a second side facing the first side, and the second side of the bank layer may have a cross-section that is inclined outwardly.

Each of the emissive layer and the second electrode may extend along cross-section of the second side of the bank layer that is inclined outwardly.

The second side of the bank layer may extend further toward a surface of the substrate compared to the first side of the bank layer.

The second side of the bank layer may have an inclination angle greater than an inclination angle of the first side of the bank layer.

The first electrode may be a transmissive electrode and the second electrode may be a reflective electrode.

The display device may further include a color control pattern disposed to correspond to the emission area between the substrate and the light emitting diode.

The display device may further include a driving thin film transistor disposed on the substrate and connected to the light emitting diode.

The driving thin film transistor may include an oxide semiconductor.

In some implementations, light from the light emitting diode is reflected on the cholesteric liquid crystal within the bank layer and emitted finally to the display surface. The luminance of the light emitted to the display surface through the emission area and light extraction efficiency (or out-coupling efficiency) can be improved.

In some implementations, light incident in the viewing angle can be reflected from the bank layer including the cholesteric liquid crystal and can be emitted to the display surface. The bank layer acts as a first mirror. Incident light in the front direction can be reflected in the second electrode disposed on the emissive layer, and the second electrode may act as a second mirror.

Incident light in the viewing angle direction may be reflected from the cholesteric liquid crystal and concentrated in the emission area. Incident light in the front direction may be reflected from the second electrode and concentrated in the emission area.

In other implementations, incident light in the viewing angle direction and incident light in the front direction may be reflected from the bank layer including the cholesteric liquid crystal by controlling the orientation of the cholesteric liquid crystal molecule.

Both reflected light in the front direction and reflected light in the viewing angle direction can be emitted to the display surface. A display device capable of minimizing a difference in color change rate and a difference in visibility in the front direction and the viewing angle direction is implemented.

Light can be reflected from each of the bank layer and the reflective electrode. There is no need to increase a height of a planarization layer disposed between the thin film transistor and the light emitting diode. Even if the inclination angle of the bank layer and the reflective electrode is not increased as the height of the planarization increases, the light luminance of the display device can be improved.

Leakage of light from the viewing angle incident on the planarization layer due to the increase in the height of the planarization layer can be prevented. It is possible to minimize color mixing in adjacent pixel regions. When the reflective electrode is disposed, process difficulty due to a high inclination angle can be minimized, and pixel defects and disconnects due to a decrease in a thickness of the reflective electrode can be prevented.

The display device has improved flexibility, and thus a foldable display device in which the display area is folded may be implemented. The display device according to implementations of the disclosure exhibits good luminance even at low power consumption. The display device provides an advantage of low-power and can implement ESG.

### BRIEF DESCRIPTION OF THE DRAWINGS

FIG. 1 illustrates a schematic block diagram of a display device according to one or more implementations of the present disclosure.

FIG. 2 illustrates a schematic block diagram of a sub-pixel shown in FIG. 1.

FIG. 3 illustrates a schematic circuit diagram of a display device according to one or more implementations of the present disclosure.

FIG. 4 illustrates a schematic cross-sectional view of the display device in accordance with a first implementation of the present disclosure.

FIG. 5 is a schematic diagram illustrating reflection and transmission of light incident from a cholesteric liquid crystal included in a bank layer in accordance with one or more implementations of the present disclosure.

FIG. 6 is a graph illustrating wavelengths of reflected light by viewing angles in cholesteric liquid crystal included in a bank layer in accordance with one or more implementations of the present disclosure.

FIG. 7 is a graph illustrating reflectance by wavelengths in cholesteric liquid crystal included in a bank layer in accordance with one or more implementations of the present disclosure.

FIG. 8 is a schematic diagram illustrating reflection of light from a bank layer and an electrode in accordance with one or more implementations of the present disclosure.

FIG. 9 is a schematic diagram illustrating that light incident on a bank layer is reflected when an orientation of a cholesteric liquid crystal included in a bank layer is randomly designed in accordance with one or more implementations of the present disclosure.

FIG. 10 illustrates a schematic exploded perspective view of a display device in accordance with another implementation of the present disclosure.

FIG. 11 illustrates a schematic cross-sectional view of the display device in accordance with another implementation of the present disclosure.

FIGS. 12 and 13 are graphs measuring front luminance and viewing angle luminance in a display device applying a bank layer structure in which infrared cholesteric liquid crystals are dispersed in accordance with an example of the present disclosure.

### DETAILED DESCRIPTION

Implementations of the present disclosure can provide a display device capable of improving luminance and minimizing color change rate.

A display device according to one or more implementations is capable of maintaining and/or improving luminance and improving light extraction efficiency.

A display device according to one or more implementations is capable of improving light extraction efficiency to incident light in a viewing angle direction and/or a front direction.

A display device according to one or more implementations is capable of emitting uniform intensity light in the viewing angle direction and the front direction.

A display device according to one or more implementations is capable of minimizing color change rate and visibility difference in the viewing angle direction and the front direction.

A display device according to one or more implementations is capable of minimizing color mixing in adjacent sub-pixel regions and preventing pixel defects and disconnection.

A display device according to one or more implementations is capable of improving flexibility and applicable to a foldable product.

A display device according to one or more implementations is capable of implementing low reflection and low power, thereby being environmentally friendly and pursuing ESG (Environmental, Social and Governance).

Additional features of the inventive concepts will be set forth in the description which follows, and in part will be apparent from the description, or may be learned by practice of the inventive concepts.

In the following description, for the purposes of explanation, numerous specific details are set forth in order to provide a thorough understanding of various implementations. The implementations are non-limiting examples of devices or methods employing one or more of the inventive concepts disclosed herein. It is apparent, however, that various implementations may be practiced without these specific details or with one or more equivalent arrangements. In other instances, well-known structures and devices are shown in block diagram form in order to avoid unnecessarily obscuring various implementations. Further, various implementations may be different, but do not have to be exclusive. For example, specific shapes, configurations, and characteristics of an implementation may be used or implemented in another implementation without departing from the inventive concepts.

Unless otherwise specified, the illustrated implementations are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various implementations may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an implementation may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular implementations and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various implementations are described herein with reference to sectional and/or exploded illustrations that are schematic illustrations of idealized implementations and/or intermediate structures. As such, variations from the shapes of the illustrations as a result, for example, of manufacturing techniques and/or tolerances, are to be expected. Thus, implementations disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some implementations are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some implementations may be physically separated into two or more interacting and discrete blocks, units, and/or modules without departing from the scope of the inventive concepts. Further, the blocks, units, and/or modules of some implementations may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

In analyzing a component, an error range should be interpreted as being included even where there is no explicit description.

Reference will now be made in detail to aspects of the disclosure, examples of which are illustrated in the accompanying drawings. Wherever possible, the same reference numbers will be used throughout the drawings to refer to the same or like parts.

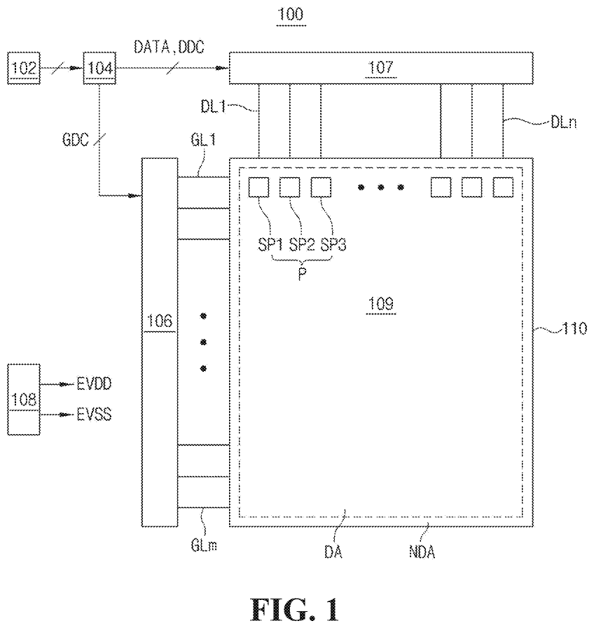

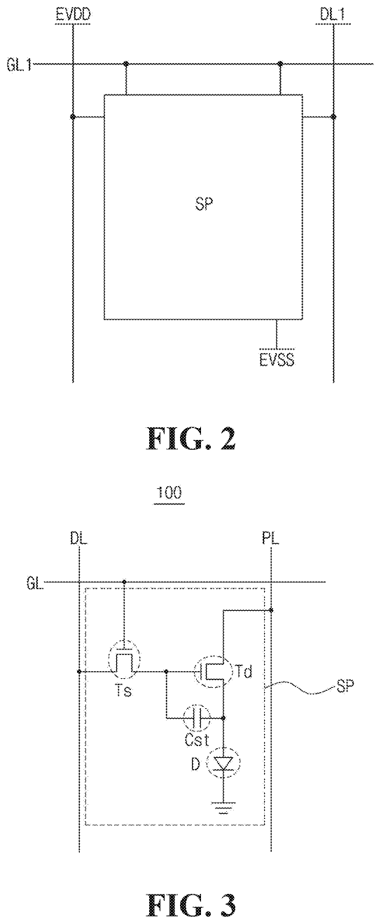

FIG. 1 illustrates a schematic block diagram of a display device according to one or more implementations of the present disclosure. FIG. 2 illustrates a schematic block diagram of a sub-pixel shown in FIG. 1.

Referring to FIG. 1, a display device 100 in accordance with one or more implementations includes an image processor 102, a timing controller 104, a gate driver 106, a power supply 108 and a substrate 110 on which a display panel 109 is disposed.

The image processor 102 outputs an image data provided from outside and driving signal for driving various apparatuses. For example, the driving signal output from the image processor 102 may include a data enable signal, a vertical synchronization signal, a horizontal synchronization signal, a clock signal, and the like.

The timing controller 104 receives the image data and the driving signal and the like from the image processor 102. The timing controller 104 generates and outputs a gate timing control signal GDC for controlling operation timing of the gate driver 106 and a data timing control signal DDC for controlling operating timing of the data driver 107 based upon the driving signal output from the image processor.

The gate driver 106 generates a scan signal and outputs the scan signal to the display panel 109 disposed on the substrate 110 in response to the gate timing control signal GDC supplied from the timing controller 104. The gate driver 106 outputs the scan signal through a plurality of gate lines GL1~GLm (m is an integer of two or more). The gate driver 106 may be located only on one side of the substrate 110 or divided into two to be located on both sides of the substrate 110 depending on the driving method. For example, the gate driver 106 may be formed in the form of an integrated circuit (IC), but is not limited thereto.

The data driver 107 generates a data signal (data voltage) and outputs the data signal to the display panel 109 in response to the data timing control signal DDC input from the timing controller 104. The data driver 107 samples and latches the data signal DATA of a digital format supplied from the timing controller 104 and converts the digital data signal DATA into the data voltage of an analog format based upon gamma voltage. The data driver 107 outputs the data signal through a plurality of data lines DL1~DLn (n is an integer of two or more). In one implementation, the data driver 107 may be formed in the form of an IC (Integrated Circuit), but is not limited thereto.

The power supply 108 outputs and supplies high potential voltage VDD and low potential voltage VSS, and the like to the display panel 109. The high potential voltage VDD is supplied to the display panel 109 through a first power line EVDD and the low potential voltage VSS is supplied to the display panel 109 through a second power line EVSS. The voltages output from the power supply 108 are output to the gate driver 106 or the data driver 107 and used for driving thereof.

The display panel 109 may be disposed on a display area DA of the substrate 110. The display panel 109 display an image in response to the data voltage and the scan signal supplied from the gate driver 106 and the data driver 107, and the voltage supplied from the power supply 108.

The substrate 110 may be divided into a display area DA displaying an image and including a plurality of pixels P and a non-display area NDA enclosing the display area DA.

The non-display area NDA is arranged outside of the display area DA, i.e., an edge of the substrate 110. A pad member is disposed in the non-display area NDA. The pad member may be connected to an electrode disposed in the display panel 109 via an output line and connected to the gate driver 106 and/or the data driver 107 via an input line.

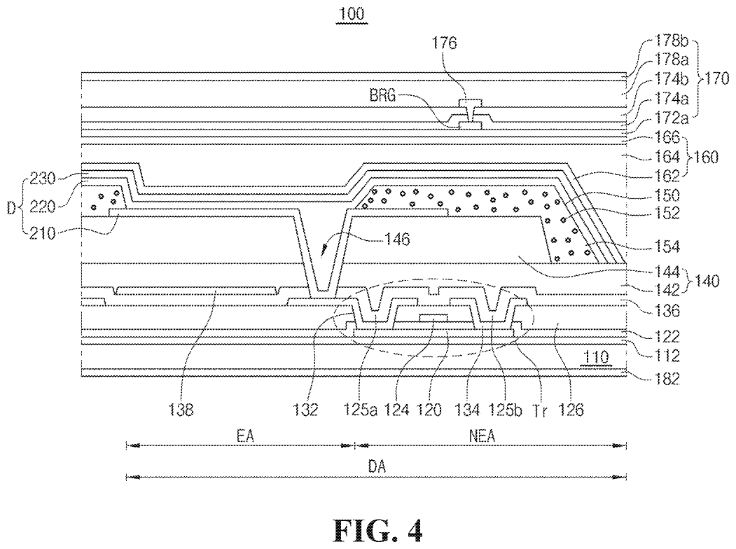

The display area DA of the substrate 110 display an image using the gate signal and the data signal. The substrate 110 may include a plurality of pixels Ps, a plurality of gate lines GLs, a plurality of data lines DLs and a plurality of power lines PLs (FIG. 3) for displaying the image. The pixel P may include a first sub-pixel SP1, a second sub-pixel SP2, a third sub-pixel SP4, and optionally, a fourth sub-pixel. For example, the first subpixel SP1 may be a red (R) sub-pixel, the second sub-pixel may be a green (G) sub-pixel, the third sub-pixel SP4 may be a blue (B) sub-pixel, and the fourth sub-pixel may be a white (W) sub-pixel, but is not limited thereto.

Referring to FIG. 2, one sub-pixel SP may be connected to the gate line GL1, the data line DL1, the first power line EVDD and the second power line EVSS. The number of and driving method for the transistor and capacitor in the sub-pixel SP may be determined by a pixel circuit configuration.

FIG. 3 illustrates a schematic circuit diagram of a light emitting display device according to one or more implementations of the present disclosure.

Referring to FIG. 3, the display device 100 according to an implementation includes a gate line GL, a data line DL, and a power line PL crossing each other to define a sub-pixel SP. A switching thin film transistor Ts, a driving thin film transistor Td, a storage capacitor Cst, and a light emitting diode D may be disposed in the sub-pixel SP.

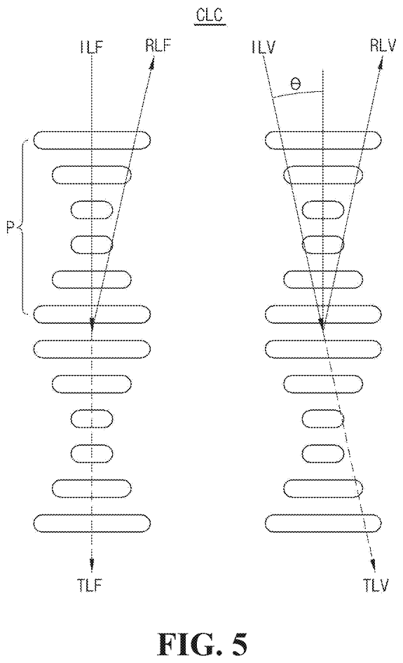

The switching thin film transistor Ts is connected to the gate line GL and the data line DL. The driving thin film transistor Td and the storage capacitor Cst are connected between the switching thin film transistor Ts and the power line PL, and the light emitting diode D is connected to the driving thin film transistor Td. In the display device 100, when the switching thin film transistor Ts is turned on by a gate signal applied to the gate line GL, the data signal DATA applied to the data line DL is applied a gate electrode 124 (FIG. 4) of the driving thin film transistor Td and one electrode of the storage capacitor Cst through the switching thin film transistor Ts.

The driving thin film transistor Td is turned on by the data signal DATA applied to the gate electrode 124 (FIG. 4) so that a current proportional to the data signal DATA is supplied from the power line PL to the light emitting diode D through the driving thin film transistor Td. And then, the light-emitting diode D emits light having a luminance proportional to the current flowing through the driving thin film transistor Td. In this case, the storage capacitor Cst is charged with a voltage proportional to the data signal so that the voltage of the gate electrode 124 in the driving thin film transistor Td is kept constant during one frame. In this manner, the display device 100 may display a desired image.

In one implementation, each of the switching thin film transistor Ts and/or the driving thin film transistor Td may include a polycrystalline semiconductor material such as low temperature polycrystalline silicon (LTPS) and/or an oxide semiconductor, without being limited thereto. For example, the switching thin film transistor Ts and/or the driving thin film transistor Td may be a transistor of a low temperature polycrystalline and oxide (LPTO) type including the LPTS and the oxide semiconductor, but is not limited thereto. In another implementation, the driving thin film transistor Td may be a transistor of a Complementary Metal Oxide Semiconductor (CMOS) type combining a p-Channel Metal Oxide Semiconductor (PMOS) and an n-Channel Metal Oxide Semiconductor (NMOS), but is not limited thereto.

### First Implementation

FIG. 4 illustrates a schematic cross-sectional view of the display device according to a first implementation of the present disclosure.

Referring to FIG. 4, the display device 100 according to the first implementation includes the substrate 110, a thin film transistor Tr and the light emitting diode D disposed on the substrate 110 in each sub-pixel SP, a bank layer 150 disposed adjacently to the light emitting diode D and a color control pattern 138 disposed between the substrate 110 and the light emitting diode D.

The substrate 110 includes the display area DA and the non-display area NDA (FIG. 1) surrounding the display area DA. The display area DA may include an emission area EA where light emitted from the light emitting diode D transmits and a non-emission area NEA disposed adjacently to the emission area EA or surrounds the emission area EA.

The substrate 110 may include, but is not limited to, a glass substrate, a flexible substrate, or a polymer plastics substrate. For example, the substrate 110 may be configured to have at least one of a polyimide (PI) substrate, a polyether sulfone (PES) substrate, a polyethylene naphthalate (PEN) substrate, a polyethylene terephthalate (PET) substrate, and a polycarbonate (PC) substrate, but is not limited thereto.

A first buffer layer 112 may be disposed on the substrate 110. The first buffer layer 112 is disposed on entire substrate 110, improves adhesion force among the substrate 110 and other layers disposed on the substrate 110, and blocks alkali substance and the like leaking from the substrate 110. In addition, the first buffer layer 112 may delay diffusion of moisture or oxygen that has penetrated the substrate 110.

For example, the first buffer layer 112 may include, but is not limited to, inorganic material such as silicon oxide (SiOx) and/or silicon nitride (SiNx) (wherein 0<x≤2). The first buffer layer 112 may have a mono-layer structure or a multi-layer structure. In one implementation, when the first buffer layer 112 has the multi-layered structure, the first buffer layer 112 may be formed by alternating SiOx and SiNx, but is not limited thereto. In some implementations, the first buffer layer 112 may be omitted depending on the type and material of the substrate 110, and the structure and type of the thin film transistor Td, and the like.

The thin film transistor Tr is disposed on the substrate 110 or the first buffer layer 112. For example, the thin film transistor Tr may include a semiconductor layer 120, a gate electrode 124, a source electrode 132, and a drain electrode 134. As an example, the thin film transistor Tr may be formed as the driving thin film transistor Td (FIG. 3).

The semiconductor layer 120 may be disposed on the substrate 110. In one implementation, the semiconductor layer 120 may include an oxide semiconductor material. For example, the oxide semiconductor may be selected from, but is not limited to, Indium Gallium Zinc oxide (IGZO), Indium Zinc Tin oxide (IZTO), Zinc Gallium Tin oxide (ZGTO), Zinc Tin oxide (ZTO), Zinc Gallium oxide (ZGO), Zinc oxide (ZnO), and combinations thereof. When the semiconductor layer 120 includes the oxide semiconductor material, a light shielding pattern may be disposed under the semiconductor layer 120. The light shielding pattern may prevent light from being incident on the semiconductor layer 120, thereby preventing or at least suppressing light-induced degradation of the semiconductor layer 120.

In another implementation, the semiconductor layer 120 may include a polycrystalline semiconductor. In this case, impurity may be doped to both sides of the semiconductor layer 120. The semiconductor layer 120 may include a central channel area without the doped impurity and a source area and a drain area located at both sides of the channel area and doped with impurities.

A gate insulating layer 122 may be disposed on the semiconductor layer 120 and cover the entire substrate 110. For example, the gate insulating layer 122 may include, but is not limited to, an inorganic insulating material such as silicon oxide (SiOₓ) and/or silicon nitride (SiNₓ) (wherein 0<x≤2). The gate insulating layer 122 may have a mono-layer structure or a multi-layer structure.

The gate electrode 124 including a conductive material such as metal is disposed on the gate insulating layer 122, at a position corresponding to a center of the semiconductor layer 120. For example, the gate electrode 124 may include, but is not limited to, a metal component such as copper (Cu), molybdenum (Mo), titanium (Ti), aluminum (Al), gold (Au), and silver (Ag). The gate electrode 124 may have a mono-layer structure or a multi-layer structure. In FIG. 4, while the gate insulating layer 122 may be disposed on the entire substrate 110, in some implementations, the gate insulating layer 122 may be patterned to have a shape that conforms to the shape of the gate electrode 124.

An interlayer insulating layer 126 is disposed on the gate electrode 124 and may cover the entire substrate 110. For example, the interlayer insulating layer 126 may include, but is not limited to, an inorganic insulating material such as silicon oxide (SiOₓ) and silicon nitride (SiNₓ) (wherein 0<x≤2) or an organic insulating material such as benzocyclobutene and/or photo-acryl. The interlayer insulating layer 126 may have a mono-layer structure or a multi-layer structure.

The interlayer insulating layer 126 has first and second semiconductor contact holes 125a and 125b that expose or do not cover both sides of the semiconductor layer 120. The first and second semiconductor contact holes 125a and 125b are spaced apart from the gate electrode 124 at both sides of the gate electrode 124. In FIG. 4, the first and second semiconductor contact holes 125a and 125b are exemplarily illustrated as being disposed in both of the interlayer insulating layer 126 and the gate insulating layer 122. However, the inventive concepts are not limited thereto. In another implementation, when the gate insulating layer 122 is patterned to have a shape that conforms to the shape of the gate electrode 124, the first and second semiconductor contact holes 125a and 125b may be formed only in the interlayer insulating layer 126.

The source electrode 132 and the drain electrode 134 including a conductive material such as metal component are disposed on the interlayer insulating layer 126. The source electrode 132 and the drain electrode 134 are spaced apart from each other with the gate electrode 124 therebetween, and electrically contact both sides of the semiconductor layer 120 through the first and second semiconductor contact holes 125a and 125b. In one implementation, the source electrode 132 may be an input electrode electrically connected to a high potential driving power and the drain electrode 134 may be an output electrode electrically connected to a switch circuit, but is not limited thereto. The amount of current flowing to the light emitting diode D may be controlled by voltage differences between the gate electrode 124 and the source electrode 132.

For example, the source electrode 132 and the drain electrode 134 may include, but is not limited to, the metal component such as copper (Cu), molybdenum (Mo), titanium (Ti), aluminum (Al), gold (Au), and/or silver (Ag). The source electrode 132 and the drain electrode 134 may have a mono-layer structure or a multi-layer structure.

In FIG. 4, the thin film transistor Tr is exemplarily illustrated as having a coplanar structure where the gate electrode 124, the source electrode 132, and the drain electrode 134 are disposed on the semiconductor layer 120. However, the inventive concepts are not limited thereto, and in another implementation, the thin film transistor may have an inverted staggered structure where the gate electrode is disposed under the semiconductor layer and the source electrode and the drain electrode are disposed on the semiconductor layer. In this case, the semiconductor layer may include amorphous silicon.

The thin film transistor Tr may be the driving thin film transistor Td (FIG. 3). For example, the driving thin film transistor Td may include the oxide semiconductor, but is not limited thereto.

A passivation layer 136 is disposed on the source electrode 132 and the drain electrode 134 and covers the entire substrate 110. The passivation layer 136 is formed with covering the thin film transistor Tr.

The color control pattern 138 is disposed correspondingly to the emission area EA on the passivation layer 136. In one implementation, the color control pattern 138 may be a color filter pattern.

In one implementation, when the color control pattern 138 is the color filter pattern, and the sub-pixel SP includes the first sub-pixel SP1, the second sub-pixel SP2 and the third sub-pixel SP3, which may be the red (R) sub-pixel, the green (G) sub-pixel and the blue (B) sub-pixel, respectively, the color control pattern 138 may include a red color filter pattern corresponding to the first sub-pixel SP1, a green color filter pattern corresponding to the second sub-pixel SP2 and a blue color filter pattern corresponding to the third sub-pixel SP3.

The red color filter pattern may include at least one of a red dye or a red pigment, the green color filter pattern may include at least one of a green dye or a green pigment, and the blue color filter pattern may include at least one of a blue dye or a blue pigment.

In another implementation, the color control pattern 138 may be a color conversion layer. In this case, the color control pattern may include a red color conversion layer corresponding to the first sub-pixel SP1, a green color conversion layer corresponding to the second sub-pixel SP2, and a blue color conversion layer corresponding to the third sub-pixel SP3. The red color conversion layer may include red quantum-dots, the green color convers may include green quantum-dots, and the blue color conversion layer may include blue quantum-dots. In some implementations, the blue color conversion layer corresponding to the third sub-pixel SP3 may be omitted.

In another implementation, the color control pattern 138 may include the color filter pattern and the color conversion layer. For example, the color conversion layer may be disposed between the light emitting diode D and the substrate 110, and the color filter pattern may be disposed between the color conversion layer and the substrate 110, but is not limited thereto.

A surface of the substrate 110 on which the thin film transistor T4 and the color control pattern 138 are arranged is not flat and has a large step difference. However, an emissive layer 200 constituting the light emitting diode D must be arranged on a flat surface to realize uniform light emission. In order to make the surface of the substrate 110 even, a planarization layer 140 may be arranged on the passivation layer 136. In one implementation, the planarization layer 140 may have a multi-layer structure. For example, the planarization layer 140 may include, but is not limited to, a first planarization layer 142 (which can implement a first overcoat layer) disposed on the passivation layer 136 and a second planarization layer 144 (which can implement a second overcoat layer) disposed on the first planarization layer 142 (first overcoat layer). In another implementation, the planarization layer 140 (which can implement an overcoat layer) may have a single-layer structure.

The planarization layer 140 (or overcoat layer) has a flat top surface and a contact hole 146 that exposes or does not cover the source electrode 132 or the drain electrode 134. For example, the planarization layer 140 may include, but is not limited to, an inorganic insulating material such as silicon oxide (SiOₓ) and silicon nitride (SiNₓ) (wherein 0<x≤2) or an organic insulating material such as benzocyclobutene and/or photo-acryl.

The light emitting diode D is disposed on the planarization layer 140 correspondingly to the emission area EA. The light emitting diode D includes a first electrode 210 disposed on the planarization layer 140 and electrically connected to the source electrode 132 or the drain electrode 134 of the thin film transistor Tr, and an emissive layer 220 and a second electrode 230 that are laminated sequentially on the first electrode 210. For example, the light emitting diode D may be positioned in each of the red sub-pixel, the green sub-pixel, and the blue sub-pixel and emit red light, green light, and blue light, respectively.

The first electrode 210 may be disposed separately in each sub-pixel SP. The first electrode 210 may be an anode and may be a transmissive electrode. The first electrode 210 may include a conductive material with relatively high work function value, for example, a transparent conductive oxide (TCO). For example, the first electrode 210 may include, but is not limited to, Indium Tin oxide (ITO), Indium Zinc oxide (IZO), Indium Tin Zinc oxide (ITZO), Tin oxide (SnO), Zinc oxide (ZnO), Indium Copper oxide (ICO) and/or Aluminum Zinc oxide (AZO).

The bank layer 150 is disposed on the planarization layer 140 and correspond to the non-emission area NEA and may cover the periphery of the first electrode 210. The bank layer 150 may be a kind of a partition wall that defines each sub-pixel SP. The bank layer 150 partitions each sub-pixel SP to prevent light of a specific color emitted from adjacent sub-pixels from being mixed.

The bank layer 150 exposes or do not cover the center of the first electrode 210 corresponding to the sub-pixel SP. The bank layer 150 includes a plurality of cholesteric liquid crystals (CLC) 152 and a matrix 154 in which the plurality of cholesteric liquid crystals 152 are dispersed. Light emitted from the light emitting diode is reflected from the cholesteric liquid crystal 152, and the bank layer 150 can function as a first mirror, which will be described in more detail below.

The emissive layer 220 is disposed on the first electrode 210. In one implementation, the emissive layer 220 may have a mono-layer structure of an emitting material layer (EML). The EML may include an organic luminescent material or an inorganic luminescent material. In particular, the light emitting display device 100 may be an organic light emitting display device or an inorganic light emitting display device.

In another implementation, the emissive layer 220 may have a multi-layer structure. For example, the emissive layer 220 may have a multi-layer structure by further including at least one of a hole injection layer (HIL), a hole transport layer (HTL), an electron blocking layer (EBL), a hole blocking layer (HBL), an electron transport layer (ETL) and an electron injection layer (EIL) in addition to the emitting material layer.

In one implementation, the emissive layer 220 may consist of a single emitting unit of one stack structure. In another implementation, the emissive layer 220 may have a tandem structure having a plurality of stacks or a plurality of emitting units. In this case, a charge generation layer (CGL) may be disposed between each of the plurality of emitting units, and each emitting unit may include at least one emitting material layer.

In one implementation, the emissive layer 220 may include, but is not limited to, an organic emissive layer or an inorganic emissive layer, for example, a nano-sized material layer, quantum dots, a micro LED emissive layer and/or a mini LED emissive layer.

The second electrode 230 is disposed on the substrate 110 onto which the emissive layer 220 is disposed. The second electrode 230 may be disposed on the entire display area DA and include a conductive material with relatively low work function value to function as a cathode. The second electrode 230 may be a reflective electrode. For example, the second electrode 230 may include, but is not limited to, lithium (Li), aluminum (Al), magnesium (Mg), calcium (Ca), silver (Ag), cesium (Cs), fluoride thereof (e.g., LiF and/or CaF), combinations thereof (e.g., LiF/Al, CsF/Al, Ca/Ag and/or LiF/Ca/Ag), and/or alloys thereof (e.g., Mg:Ag, Ca:Ag, LiF/Mg:Ag and/or LiF/Ca:Ag).

When the light emitting diode D is exposed to moisture or oxygen, defects such as pixel shrinkage phenomenon which reduces the emission area or dark spots within the emission area may be caused. In addition, moisture or oxygen oxidizes metal electrodes. An encapsulation layer or encapsulation film 160 blocks penetration of moisture and oxygen from outside, thereby preventing defects in the light emitting diode D and various electrodes.

The encapsulation layer 160 may be disposed on the second electrode 230. In one implementation, the encapsulation layer 160 may include a first encapsulation layer 162, a second encapsulation layer 164 and a third encapsulation layer 166. In another implementation, the encapsulation layer 160 may include two layers or four or more layers.

For example, each of the first encapsulation layer 162 and the third encapsulation layer 166 may have a mono-layer structure or a multi-layer structure of an inorganic insulating material such as silicon oxide (SiOₓ) and silicon nitride (SiNₓ) (wherein 0<x≤2), but is not limited thereto. Optionally, the first encapsulation layer 162 and the third encapsulation layer 166 may further include an organic material between inorganic materials such as SiOx, SiON, SiNx (0<x≤2), but is not limited thereto. The second encapsulation layer 164 may include, but is not limited to, an organic material such as an epoxy resin.

A touch sensor (touch panel) 170 may be disposed on the encapsulation layer 160 to provide a sensing function with the display device 100. For example, the touch sensor 170 may include a bridge electrode or a connection electrode BRG and a touch electrode 176, and may further include a plurality of insulating layers and/or buffer layers.

In one implementation, the touch sensor 170 may include a second buffer layer 172a, a first touch insulating layer 174a, a second touch insulating layer 174b and a plurality of touch electrodes 176. In addition, the touch sensor 170 may further include an organic insulating layer 178a and a third buffer layer 178b covering the second touch insulating layer 174b and the touch electrode 176. In some implementations, the touch sensor 170 may be omitted.

The second buffer layer 172a is disposed on the third encapsulation layer 166 of the encapsulation layer 160. The second buffer layer 172a is disposed directly on the third encapsulation layer 166 to improve adhesion forces between the touch sensor 170 and the third encapsulation layer 166. The second buffer layer 172a may have a mono-layer structure or a multi-layer structure. The second buffer layer 172a may include an inorganic insulating material. For example, the second buffer layer 172a may include, but is not limited to, an inorganic insulating material selected from silicon oxide (SiOₓ), silicon nitride (SiNₓ,), aluminum oxide (AlOₓ) (wherein 0<x≤2), and a combination thereof.

The bridge electrode BRG is disposed on the second buffer layer 172a and the first touch insulating layer 174a is disposed to cover the bridge electrode BRG. The second touch insulating layer 174b is disposed on the first touch insulating layer 174a and the plurality of touch electrodes 176 may be disposed on the first and second touch insulating layers 174a and 174b.

The bridge electrode BRG may be electrically connected to at least a portion of the plural touch electrodes 176. The first touch insulating layer 174a and the second touch insulating layer 174b may have a contact hole that exposes or do not cover the bridge electrode BRG. In this case, adjacent touch electrodes 176 may electrically contact the bridge electrode BRF through the contact hole to be electrically connected to each other.

The first touch insulating layer 174a and the second touch insulating layer 174b may include an inorganic insulating material and/or an organic insulating material. Optionally, each of the first touch insulating layer 174a and the second touch insulating layer 174b may have a multi-layer structure where an inorganic material layer and an organic material layer are alternately disposed. For example, the first touch insulating layer 174a may include an inorganic material and the second touch insulating layer 174b may include an organic material, but is not limited thereto.

For example, the first touch insulating layer 174a may include, but is not limited to, an inorganic insulating material selected from silicon oxide (SiOₓ), silicon nitride (SiNₓ,), aluminum oxide (AlOₓ) (wherein 0<x≤2), and a combination thereof. In another implementation, the second touch insulating layer 174b may include, but is not limited to, a transparent organic insulating material selected from an acryl-containing resin, a polyester-containing resin, an epoxy-containing resin, a silicone-containing resin, and a combination thereof.

Each of the touch electrodes 176 may be disposed on the first touch insulating layer 174a and the second touch insulating layer 174b and correspond to the bank layer 150. For example, the touch electrode 176 may include, but is not limited to, a transparent metal oxide such as ITO, IZO, ITZO, SnO, ZnO, ICO, and/or AZO similar to the first electrode 210.

In addition, the organic insulating layer 178a may be disposed on the touch electrode 176 to cover the entire display area DA of the substrate 110. The third buffer layer 178b may be disposed on the organic insulating layer 178a to cover the entire display area of the substrate 110. The third buffer layer 178b protects the touch sensor 170 from damage. The third buffer layer 178b may include inorganic oxide and/or inorganic nitride.

A polarizing film 182 may be disposed under the substrate 110. In one implementation, the polarizing film 182 may be a circular polarizing film, but is not limited thereto.

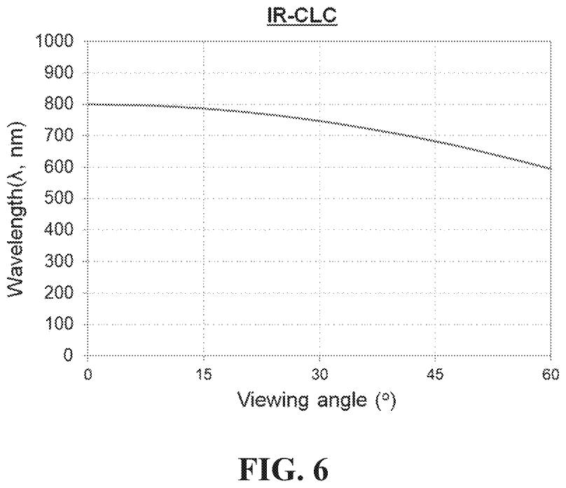

At least a portion of the light incident on the cholesteric liquid crystal 152 included in the bank layer 150 is reflected toward the display surface, so that the bank layer 150 can function as a mirror, which will be described below. FIG. 5 is a schematic diagram illustrating reflection and transmission of light incident from a cholesteric liquid crystal included in a bank layer in accordance with one or more implementations of the present disclosure.

The cholesteric liquid crystals CLCs can be fabricated by adding chiral dopants, which create a cholesteric phase, to liquid crystal molecules. Chiral dopants exhibit temperature-dependent solubility in liquid crystal molecules and induce a periodic helical structure in the liquid crystal molecules.

When nematic liquid crystal molecules are doped with chiral dopants, a cholesteric liquid crystal (CLC) polymer is formed, which has a cholesteric phase in which the nematic liquid crystal's directors are twisted along the helical axis. Thus, a CLC has a molecular conformation in which the directors of the liquid crystal molecules are repeatedly twisted at regular intervals along the helical axis of the liquid crystal molecules. The periodicity of the helical repetition of the liquid crystal molecules is called the pitch P.

When the wavelength of incident light on a CLC is similar to the pitch P, the CLC selectively reflects light of a specific wavelength through Bragg reflection, while the remaining light passes through the liquid crystal molecules in a helical pattern due to the molecular structure twisted within the pitch P. That is, cholesteric liquid crystals CLCs reflect light having a specific rotational polarization direction for incident light of a specific wavelength that matches the rotational direction of the helical structure in the liquid crystal molecules and the pitch P of the liquid crystal molecules, and transmit the remaining light.

For example, when the helical structure of the liquid crystal molecules in the cholesteric liquid crystal CLC rotates right-handed, right-circularly polarized light is reflected, and left-circularly polarized light is transmitted among the incident light. Conversely, when the helical structure of the liquid crystal molecules in the cholesteric liquid crystal CLC rotates left-handed, left-polarized light is reflected, and right-circularly polarized light is transmitted among the incident light.

Meanwhile, the pitch P in the cholesteric liquid crystal CLC varies depending on the chiral dopant content. Generally, as the chiral dopant content increases, the pitch P decreases, shifting the reflected wavelength band to shorter wavelengths.

Referring to FIG. 5, in the cholesteric liquid crystals CLCs, some of the front-incident light ILF parallel to a helical axis of the liquid crystal molecules is reflected as front reflection light RLF, and the remainder is transmitted as front transmission light TLF. Some of the incident light ILV in the viewing angle θ direction with respect to the helical axis of the liquid crystal molecules is reflected as viewing angle reflection light RLV, and the remainder is transmitted as viewing angle transmission light TLV.

The front reflection light RLF for the front-incident light ILF parallel to the helical axis of the liquid crystal molecules has different reflection wavelength from the viewing angle reflection light RLV for the incident light ILV in the viewing angle θ with respect to the helical axis of the liquid crystal molecule. The maximum reflection wavelength (λ₀) of the front reflection light RLF for the front-incident light ILF parallel to the helical axis of the liquid crystal molecules in the cholesteric liquid crystal CLC can be expressed as Equation (1) below:

λ₀=p*n (1)

In Equation (1), p is the pitch of the liquid crystal molecule, and n is an average refractive index of the liquid crystal molecule.

Meanwhile, a reflection wavelength band in the cholesteric liquid crystal CLC can be calculated using the following equation (2):

Δλ=p*Δn (2)

In Equation (2), Δλ is a reflection wavelength band, p is the pitch of the liquid crystal molecule, and Δλ indicates a difference between an ordinary refractive index (no) in the direction parallel to the direction of the liquid crystal molecules and the extraordinary refractive index (ne) in the direction perpendicular to the direction of the liquid crystal molecules.

On the other hand, the maximum reflection wavelength (λθ) of the viewing angle reflection light RLV for the incident light ILV in the cholesteric liquid crystal CLC along the viewing angle (θ) can be expressed as Equation (3):

λ_{θ}=p*n*cos (sin⁻¹ sin θ/n) (3)

In Equation (3), p and n are defined as in Equation (1), and θ represents the viewing angle relative to the helical axis of the liquid crystal molecules.

When the viewing angle θ is 0 degrees (frontal incidence parallel to the helical axis of the liquid crystal molecules), Equation (3) can be reduced to Equation (1).

According to Equation (3), the maximum reflection wavelength λ_{θ} of the viewing angle reflection light RLV for the incident light ILV along the viewing angle θ in the cholesteric liquid crystal CLC depends on p*n*cosθ. Therefore, in the cholesteric liquid crystal CLC having a planar texture, the maximum reflection wavelength λ₀ in the front direction calculated by Equation (1) is different from the maximum reflection wavelength λ_{θ} in the viewing angle θ direction calculated by Equation (3).

In the cholesteric liquid crystal CLC, the maximum reflection wavelength λ_{θ} of the incident light ILV along the viewing angle θ direction relative to the helical axis of the liquid crystal molecules shifts toward shorter wavelengths compared to the maximum reflection wavelength λ₀ for the incident light ILF in the front direction parallel to the helical axis of the liquid crystal molecules. For the incident light ILV with a viewing angle θ, the viewing angle reflection light RLV with a maximum reflected wavelength λ_{θ} shifted toward shorter wavelengths is obtained, similar to the decrease in pitch P of the cholesteric liquid crystal CLC.

In one implementation, the cholesteric liquid crystal CLC dispersed within the bank layer 150 may be a cholesteric liquid crystal CLC that induces the viewing angle reflection light RLV in the visible wavelength band for the incident light ILV along the viewing angle θ relative to the axis of the liquid crystal molecules. In another implementation, the cholesteric liquid crystal CLC can induce front reflection light RLF in the infrared wavelength band for the incident light ILF in the front direction parallel to the helical axis of the liquid crystal molecules, and viewing angle reflection light RLV of visible light above the yellow wavelength band for the incident light ILV in the viewing angle θ direction relative to the helical axis of the liquid crystal molecules. For example, the cholesteric liquid crystal CLC can induce viewing angle reflection light RLV of visible light in at least a red wavelength band for the incident light ILV in the viewing angle (θ) direction relative to the helical axis of the liquid crystal molecules.

As used herein, a cholesteric liquid crystal that induces front reflection light RLF in an infrared wavelength band for the incident light ILF in the front direction may be referred to as an “infrared cholesteric liquid crystal (IR-CLC).” In addition, when the viewing angle reflection light RLV for the incident light ILV in the viewing angle (θ) direction with respect to the axis of liquid crystal molecules of the infrared cholesteric liquid crystal IR-CLC is a visible light wavelength in a wavelength band of about 570 nm or more, such as a yellow wavelength band, an orange wavelength band, and a red wavelength band, the term “above the yellow wavelength band” may be used for the reflected wavelength band of this viewing angle reflection light RLV.

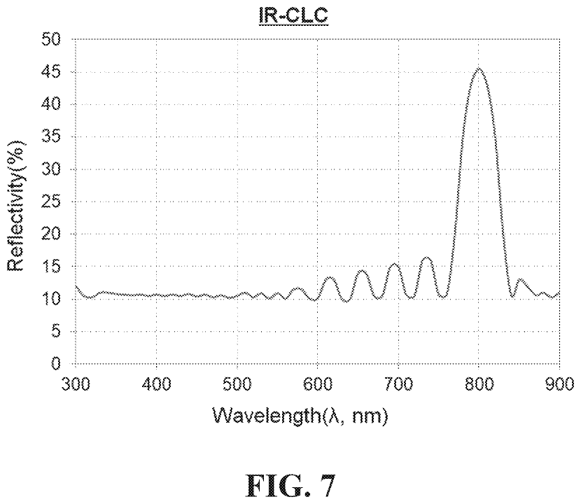

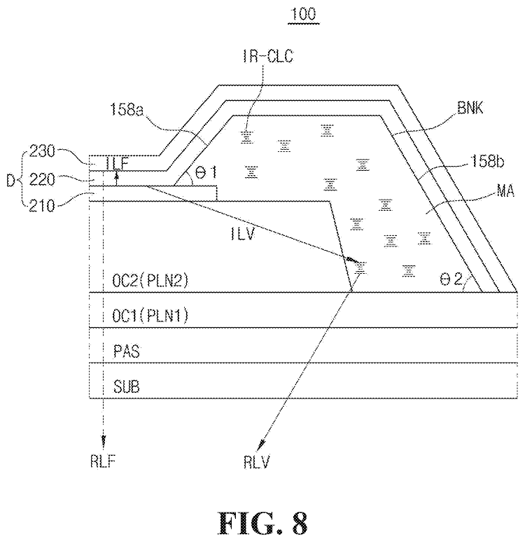

FIG. 6 is a graph illustrating wavelengths of reflection light by viewing angles in cholesteric liquid crystal included in a bank layer in accordance with one or more implementations of the present disclosure. FIG. 7 is a graph illustrating reflectance by wavelengths in cholesteric liquid crystal included in a bank layer in accordance with one or more implementations of the present disclosure.

Referring to FIGS. 5 to 7, in the infrared cholesteric liquid crystals IR-CLCs, the front reflection light RLF in the infrared wavelength band is induced for the front-direction incident light ILF parallel to the helical axis of the liquid crystal molecule. In the infrared cholesteric liquid crystals IR-CLCs, the viewing angle reflection light RLV in the visible light wavelength band above the yellow wavelength band is induced for the incident light ILV along the viewing angle θ with respect to the helical axis of the liquid crystal molecules.

In one implementation, the front reflection light RLF may have a near-infrared wavelength band and the viewing angle reflection light RLV may have a visible light wavelength band above the yellow wavelength band in the infrared cholesteric liquid crystal IR-CLC. For example, the front reflection light RLF may have wavelengths between 800 nm and 1200 nm in the infrared cholesteric liquid crystal IR-CLC, but is not limited thereto.

In another implementation, infrared light of about 800 nm wavelength band may be reflected as the front reflection light RLF in the front direction (viewing angle 0°) in the infrared cholesteric liquid crystal IR-CLC. On the other hand, as the viewing angle θ increases in the infrared cholesteric liquid crystals IR-CLCs, the viewing angle reflection light RLV shifts to shorter wavelengths and is reflected as the viewing angle reflection light RLV in the visible light wavelength band above the yellow wavelength band. Additionally, it can be seen that the reflectance is highest in the near-infrared wavelength band, and the reflectance is relatively high at the wavelength band above the yellow wavelength band within the visible light wavelength band, in the infrared cholesteric liquid crystals IR-CLCs.

In one implementation, the infrared cholesteric liquid crystal IR-CLC is transparent in the front direction (viewing angle of 0°) and may have a color in the red wavelength band in the viewing angle θ direction. By applying the infrared cholesteric liquid crystal IR-CLC to the bank layer 150, the incident light (ILF) in the front direction can be transmitted and reflected light RLV in the red wavelength band can be implemented for the incident light ILV in the viewing angle θ direction.

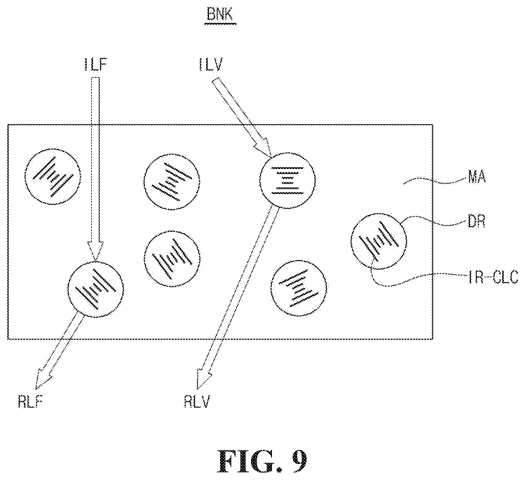

FIG. 8 is a schematic diagram illustrating reflection of light from a bank layer and an electrode in accordance with one or more implementations of the present disclosure.

Referring to FIG. 8, a passivation layer PAS, a first overcoat layer OC1 or a first planarization layer PLN1, and a second overcoat layer OC2 or a second planarization layer PLN2 are laminated sequentially on the substrate SUB of the display surface, and the light emitting diode D and the bank layer BNK are disposed on the second overcoat layer OC2 or the second planarization layer PLN2.

In one implementation, the first side 158a of the bank layer BNK, which is arranged to cover the edge of the first electrode 210 and contacts to the light emitting diode D, may have a cross-section inclined with at a first angle θ1 toward the emissive layer 220. In other words, the first side 158a of the bank layer 150 may have a cross-sectional shape that gradually increases in width toward the first electrode 210, that is, a tapered cross-sectional shape.

The first side 158a of the bank layer BNK may be curved with a predetermined curvature, or may extend toward the emissive layer 220 without curvature. For example, the first side 158 a of the bank layer BNK may be arranged to have a first angle θ1 between 30° and 90°, for example, 45° and 90°, with respect to the surface of the first electrode 210.

Each of the emissive layer 220 and the second electrode 230 may be extended along the upper surface of the bank layer BNK so that light emitted from the emissive layer 220 may be reflected from the second electrode 230 that can be the reflective electrode. In another implementation, a second side 158b of the bank layer BNK facing to the first side 158a may have a cross-section inclined outwardly. In other words, the second side 158b of the bank layer BNK may have a cross-sectional shape that gradually increases in width toward the outside, that is, a tapered cross-sectional shape.

The bank layer BNK may include the cholesteric liquid crystals CLCs and the matrix resin MA in which the cholesteric liquid crystals CLCs are dispersed. For example, the matrix resin MA may include, but is not limited to, a (meta)acrylate-containing resin, an acryl-containing resin, a cardo-containing resin, an epoxy-containing resin, an amide-containing resin, a urethane-containing resin, an acryl-amide-containing resin, an imide-containing resin, a fluorene-containing resin, a siloxane-containing resin, copolymers thereof and combinations thereof.

In FIG. 8, the infrared cholesteric liquid crystal IR-CLC is arranged in a direction perpendicular to the surface of the substrate SUB, which is the display surface. The incident light ILV in the viewing angle direction from the emissive layer 220 to the bank layer BNK is reflected from the infrared cholesteric liquid crystal IR-CLC. The incident light ILV in the viewing angle direction with respect to the spiral axis of the cholesteric liquid crystal IR-CLC is emitted as the viewing angle reflection light RLV having the visible light wavelength band above the yellow wavelength band, and is ultimately collected in the emission area EA (FIG. 4). In this case, the bank layer BNK with the infrared cholesteric liquid crystal IR-CLC dispersed therein functions as the first mirror that ultimately reflects light in the viewing angle direction among the light emitted from the emissive layer 220 to the display surface.

The second side 158b of the bank layer BNK may be curved with a predetermined curvature or extended outwardly without the curvature. As an example, the second side 158b of the bank layer BNK may be arranged with a second angle θ2 between 30° and 60°, for example, 45° to 60°, with respect to an upper surface of the first planarization layer PNL1 or the first overcoat layer OC1. In an implementation, the emissive layer 220 and the second electrode 230 may be extended along the cross-section inclined outwardly of the second side 158b of the bank layer BNK.

The first side 158a of the bank layer BNK is arranged to cover the first electrode 210 on the second planarization layer PLN2 or the second overcoat layer OC2. On the other hand, the second side 158b of the bank layer BNK may extend through the patterned second planarization layer PLN2 or the second overcoat layer OC2 to the upper surface of the first planarization layer PLN1 or the first overcoat layer OC1. That is, compared to the first side 158a of the bank layer BNK, the second side 158b of the bank layer BNK may extend downwardly toward the substrate SUB. In an exemplary implementation, the second inclination angle θ2 of the second side 158b of the bank layer BNK may be greater than the first inclination angle θ1 of the first side 158a of the bank layer BNK, but the present disclosure is not limited thereto.

According to those arrangements, not only the bank layer BNK, but also the emissive layer 220 and the second electrode 230, each of which extends along the upper surface and the second side 158b of the bank layer BNK, may have a kind of a partition structure. The incident light ILF in the front direction from the emissive layer 220 to the second electrode 230 is reflected by the second electrode 230, emitted to the display surface as the front reflection light RLF, and ultimately collected into the emission area (FIG. 4).

In other words, the front reflection light ILF from the second electrode 230 can be ultimately emitted as the front reflection light RLF. Accordingly, the front reflection light RLF from the second electrode 230, which extends along the second side 158b of the bank layer BNK at a second angle θ2 and has the partition structure, can be collected so that the display device 100 can realize beneficial front luminance. That is, in the present disclosure, the second electrode 230 can function as a second mirror that ultimately reflects light emitted from the emissive layer 200 toward the front display surface.

When the second electrode 230 having the partition structure is placed in the bank layer BNK without applying the cholesteric liquid crystal CLC such as the infrared cholesteric liquid crystal IR-CLC, the second planarization layer PLN2 or the second overcoat layer OC2 must be considerably thick to achieve efficient frontal reflection at the second electrode 220. Due to the high thickness of the second planarization layer PLN2 or the second overcoat layer OC2, light incident on the second planarization layer PLN2 or the second overcoat layer OC2 in the viewing angle, resulting in color mixing in adjacent sub-pixels SPs.

Furthermore, to achieve sufficient reflection in the second electrode 220, the second angle θ2 of the second side 158b of the bank layer BNK having the partition structure must be high. As the thickness of the second electrode 230 having the partition structure with the second angle θ2 exceeding 60° decreases, process problems such as dead pixels and disconnections arise.

In contrast, according to the present disclosure, the cholesteric liquid crystals CLCs reflect incident light ILV in the viewing angle θ (FIG. 5) toward the display surface in the form of viewing angle reflection light RLV. Accordingly, the bank layer BNK functions as the first mirror that induces the viewing angle reflection light RLV. Furthermore, the second electrode 230 having the partition structure functions as the second mirror that reflects front incident light ILF toward the display surface in the form of front reflection light RLF.

According to the present disclosure, both light incident in the front and viewing angle directions is emitted to the display surface. By forming the thin second planarization layer PLN2 or the second overcoat layer OC2, sufficient reflection light can be emitted to the display surface even without designing the second angle θ2 of the second side 158b of the bank layer BNK to be a high angle exceeding 60°. Therefore, light leakage in the viewing angle can be prevented and color mixing in adjacent sub-pixels SPs due to the increased thickness of the second planarization layer PLN2 or the second overcoat layer OC2 can be minimized.

As described above, when the incident light ILV in the viewing angle direction collides with the infrared cholesteric liquid crystal IR-CLC within the bank layer BNK, visible light above the yellow wavelength band is ultimately emitted as the viewing angle reflection light RLV. In addition, the front incident light ILF is reflected by the second electrode 230 and is ultimately emitted as the front reflection light RLF. Both the front direction and viewing angle direction light emitted from the emissive layer 220 are emitted to the display surface, so that the luminance or the brightness of the light emitted from the display device 100 is improved, thereby improving the light extraction efficiency of the display device 100. The display device 100 can exhibit sufficient brightness even at low power consumption. Accordingly, the display device 100 capable of implementing low power consumption and ESG can be manufactured.

Both the incident light ILV in the viewing direction and incident light ILF in the front direction are emitted to the display surface. The display device 100 that minimizes differences in color change rates and visual perception in the viewing direction and the front direction can be implemented.

Referring to FIGS. 6 to 8, as an example of the cholesteric liquid crystals CLCs, the infrared cholesteric liquid crystals IR-CLCs are dispersed in the bank layer BNK. In this case, the infrared cholesteric liquid crystal IR-CLC dispersed in the bank layer BNK emits reflection light RLV in the visible wavelength range above the yellow wavelength range to the display surface for the incident light ILV in the viewing direction. Conversely, in the bank layer BNK in which the infrared cholesteric liquid crystal IR-CLC is dispersed, reflection light in the infrared wavelength range is emitted for the incident light in the front direction, and reflection light in the visible wavelength range is not emitted.

In this way, when the infrared cholesteric liquid crystal IR-CRC is used in the bank layer BNK, only the viewing angle reflection light RLV corresponding to the visible light wavelength band above the yellow wavelength band is reflected for the incident light ILV in the viewing angle direction, and visible light in the blue and/or green wavelength bands, which is the visible light wavelength band below the yellow wavelength band, may not be substantially reflected. For the incident light ILV in the viewing angle direction, the viewing angle reflection light RLV that can enhance brightness while minimizing the color-changing rate can be emitted to the display surface.

In FIG. 8, the liquid crystal molecules of the infrared cholesteric liquid crystals IR-CLCs as an example of cholesteric liquid crystals CLCs dispersed within a bank layer BNK are oriented in a direction perpendicular to the surface of the substrate SUB, which is the display surface. In another implementation, the cholesteric liquid crystals CLCs dispersed within the bank layer BNK can be oriented in a random direction with respect to the display surface.

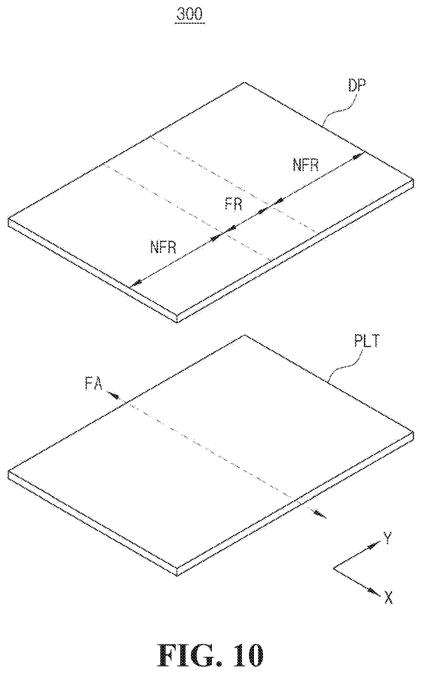

FIG. 9 is a schematic diagram illustrating that light incident on a bank layer is reflected when an orientation of a cholesteric liquid crystal included in a bank layer is randomly designed in accordance with one or more implementations of the present disclosure.

Referring to FIG. 9, the bank layer BNK may comprise the cholesteric liquid crystals CLCs, for example, the infrared cholesteric liquid crystals IR-CLCs in the formed of a droplet DR dispersed in the matrix resin MA. In FIG. 9, the liquid crystal molecules have a Polymer Dispersed Liquid Crystal (PLDC) conformation. Accordingly, each of the infrared cholesteric liquid crystals IR-CRCs may not be oriented in the specific direction, but be oriented randomly.

The incident light ILV along the viewing angle direction, as well as front incident light ILF, may not be incident in the front direction, which is parallel to the helical axis of the liquid crystal molecules constituting the infrared cholesteric liquid crystal IR-CLC. Incident light ILV along the viewing angle direction is reflected by the infrared cholesteric liquid crystal IR-CLC and emitted as the viewing angle reflection light RLV in the visible wavelength range above the yellow wavelength band. Furthermore, the incident light ILF along the front direction can also be reflected by the infrared cholesteric liquid crystal IR-CLC and emitted as the front reflection light (RLF) in the visible wavelength range of the yellow wavelength band or more.

Reflection light in the visible wavelength range of the yellow wavelength band or more along the viewing angle and front directions can be emitted and collected onto the display surface. Consequently, the brightness and light extraction efficiency of the display device can be further improved.

The bank layer BNK can be patterned using a photosensitive composition comprising a matrix resin MA, which may be a photosensitive binder resin, a solvent, a nematic liquid crystal and additives such as a chiral dopant and a dispersant. As described above, as the content of the chiral dopant added to the liquid crystal molecules increases, the reflection wavelength band of the cholesteric liquid crystal shifts toward shorter wavelengths.

Therefore, by adjusting the content of the chiral dopant added to the nematic liquid crystal molecules, the infrared cholesteric liquid crystal IR-CLC can be synthesized that exhibits front reflection light RLF in the infrared wavelength band for the front incident light ILF parallel to the helical axis of the liquid crystal molecules. For example, adding the chiral dopant at a ratio of 0.01 to 1 parts by weight, for example, 0.01 to 0.1 parts by weight, to 100 parts by weight of the nematic liquid crystal can synthesize the infrared cholesteric liquid crystal IR-CLC, but this is not limited thereto. This photosensitive composition is coated on the second planarization layer PLN2 or the second overcoat layer OC2, and a photoresist process (soft baking, exposure, development, curing/hard baking) using a mask is performed to pattern a bank layer BNK in which the cholesteric liquid crystals CLC are dispersed in a matrix resin MA.

### Second Implementation

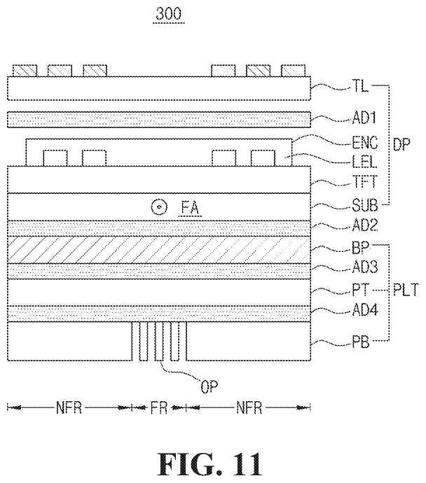

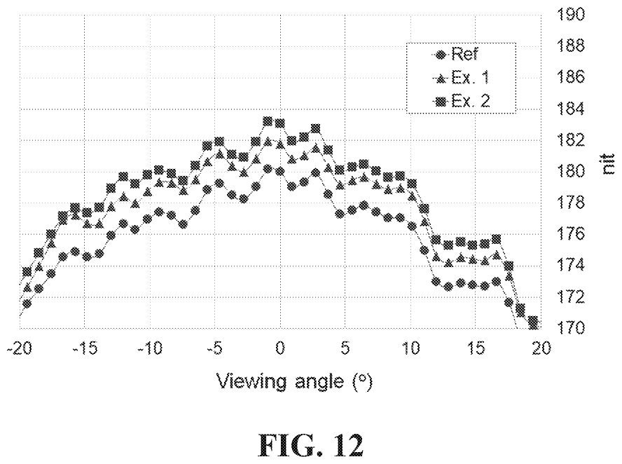

The display device in accordance with the implementations of the present disclosure may be a foldable display device. FIG. 10 illustrates a schematic exploded perspective view of a display device in accordance with another implementation of the present disclosure. FIG. 11 illustrates a schematic cross-sectional view of the display device in accordance with another implementation of the present disclosure.

Referring to FIGS. 10 and 11, a display device 300 includes a folding region FR and a non-folding region NFR, and may be folded along a first (Y) direction. The display device 300 may include the non-folding region NFR at both sides of the folding region FR along the first direction.

The display device 300 may be out-folded, in which the display surface is exposed to the outside when folded, but is not limited thereto. Alternatively or additionally, the display device 500 may be in-folded in which the display surface is hidden therein.

In one implementation, a display panel DP may be folded inwardly or outwardly with respect to a folding axis FA. As used herein, the folding axis FA represents a center of the folding area having a predetermined curvature due to folding by an imaginary line. While the display panel DP is described and illustrated as being foldable at a center portion in FIG. 8, the entire portion of the display panel DP may be freely deformed.

The display panel DP may include a substrate SUB including a flexible material so that the display area may be folded inwardly or outwardly, and an element layer for displaying an image. For example, the element layer may include a thin film transistor element layer TFT and a light emitting element layer LEL disposed in the display area on the substrate SUB.

An encapsulation layer ENC is disposed on the light emitting element layer LEL, a touch layer (touch sensor) TL is disposed on the encapsulation layer LED, and a cover window CW is disposed on the touch layer TL. In addition, a color filter layer and/or a black matrix may be disposed on the touch layer TL, for example, between the touch layer TL and the cover window CW.

A plate PLT is disposed on the lower surface of the substrate SUB for supporting the substrate SUB. For example, the plate PLT may include a back plate BP, a plate top PT, and a plate bottom PB disposed sequentially on the lower surface of the substrate SUB.

The thin film transistor element layer TFT includes a thin film transistor with a semiconductor layer, a gate electrode, a source electrode and a drain electrode, a gate insulating layer, and an interlayer insulating layer. The thin film transistor may have the structure illustrated in FIG. 4. The thin film transistor may be a driving thin film transistor and may include an oxide semiconductor.

The light emitting element layer LEL may include a light emitting diode, a bank layer, an anti-reflection pattern, and/or a column spacer. The arrangements and/or shapes of the light emitting diode, the bank layer, the anti-reflection pattern, and/or the column spacer may be substantially the same as those shown in FIGS. 4 to 9.

The substrate SUB on which the thin film transistor element layer TFT and the light emitting element layer LEL are disposed may be encapsulated by the encapsulation layer ENC. The encapsulation layer ENC prevents external oxygen and/or moisture from infiltrating to the light emitting element layer LEL.

The back plate BP may include an organic material with beneficial folding properties. For example, the back plate BP may include, but is not limited to, a polyimide (PI).

The plate top PT and the plate bottom PB may include a metal component, and the thickness of the plate bottom PB exposed to the outside may be larger than the thickness of the plate top PT. For example, the plate top PT may include SUS301 with relatively high hardness and the plate bottom PB may include SUS313 with higher corrosion resistance and acid resistance, but is not limited thereto.

The plate bottom PB includes a plurality of openings OP in the folding area FR so that the display device 300 may have improved folding property. In one implementation, the plurality of openings OP may be configured to penetrate the surface and/or rear surface of the plate bottom PB.

A plurality of adhesive components AD1, AD2, AD3 and AD4 may be disposed between the pluralities of components in the display device 300. Each of the first to fourth adhesive components AD1, AD2, AD3 and AD4 may include an optically clear adhesive (OCA) and/or a pressure sensitive adhesive (PSA).

In accordance with the second implementation, it is possible to realize the display device 300 with improving light luminance and light extraction efficiency, minimizing color change rates by front direction and the viewing angle direction, preventing color mixing between the adjacent sub-pixels, and improving process difficulty. In addition, the foldable display with beneficial flexibility may be fabricated by obviating a polarizer. The display device implementing ESG can be manufactured with the advantages of low reflection and low power.

### EXAMPLES

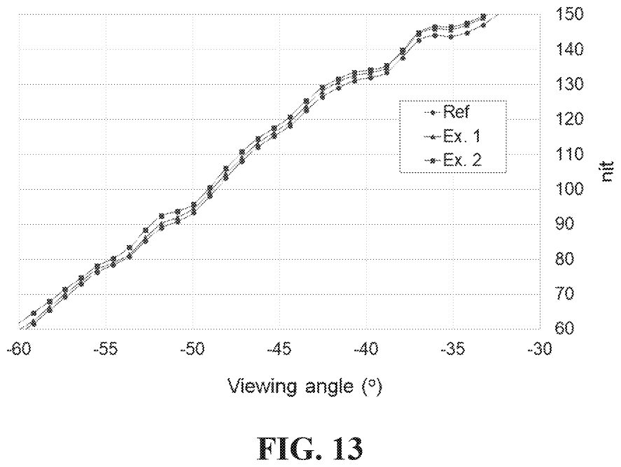

The front luminance and viewing angle luminance were evaluated in a display device having the bank layer BNK and the second electrode 230 of the partition structure illustrated in FIG. 8. In Examples 1 (Ex. 1) and 2 (Ex. 2), the infrared cholesteric liquid crystals IR-CLC were dispersed in the matrix resin inside the bank layer BNK. In Example 1 (Ex. 1), the second taper angle θ2 of the second side 158b of the bank layer BNK was designed to be 60°, and in Example 2 (Ex. 2), the taper angle θ2 was designed to be 50°. In the Comparative Example (Ref.), the infrared cholesteric liquid crystals IR-CLC were not applied inside the bank layer BNK, and the second taper angle θ2 of the second side 158b of the bank layer BNK was designed to be 60°. The results of the frontal luminance evaluation are shown in FIG. 12, and the results of the viewing angle luminance evaluation are shown in FIG. 13.

Compared to the Comparative Example (Ref.) that applied only the second electrode 230 with the partition structure and did not apply infrared cholesteric liquid crystal IR-CLC within the bank layer BNK, Examples 1 (Ex. 1) and 2 (Ex. 2) in which the bank layer BNK with the infrared cholesteric liquid crystal IR-CLC dispersed therein was applied as the first mirror and the second electrode 230 with the partition structure was applied as the second mirror showed increased luminance in both the front direction and the viewing angle direction. In particular, as in Example 2, it was confirmed that even when the taper angle θ2 was reduced, both the front luminance and the viewing angle luminance could be improved compared to the Comparative Example (Ref.).

Although certain implementations and implementations have been described herein, other implementations and modifications will be apparent from this description. Accordingly, the inventive concepts are not limited to such implementations, but rather to the broader scope of the appended claims and various obvious modifications and equivalent arrangements as would be apparent to a person of ordinary skill in the art.

What is claimed is:

1. A display device, comprising:
a substrate having an emission area and a non-emission area;
a light emitting diode disposed on the substrate in the emission area; and
a bank layer disposed in the non-emission area outside of the light emitting diode,
wherein the bank layer comprises a first side facing the light emitting diode, wherein the first side of the bank layer has a cross-section inclined toward the light emitting diode, and
wherein the bank layer comprises a cholesteric liquid crystal.

2. The display device of claim 1, wherein the cholesteric liquid crystal reflects light that is incident on the bank layer with a viewing angle.

3. The display device of claim 1, wherein the cholesteric liquid crystal reflects light that is incident on the bank layer with a viewing angle and light incident on a front direction of the bank layer.

4. The display device of claim 3, wherein the cholesteric liquid crystal reflects visible light having a wavelength greater than or equal to a yellow wavelength band with respect to incident light in a viewing angle direction based on a spiral axis of a liquid crystal molecule.

5. The display device of claim 1, wherein the cholesteric liquid crystal reflects visible light having a wavelength of a red wavelength band with respect to incident light in a viewing angle direction based on a spiral axis of a liquid crystal molecule.

6. The display device of claim 1, wherein the cholesteric liquid crystal reflects near-infrared light with respect to front incident light parallel to a spiral axis of a liquid crystal molecule.

7. The display device of claim 1, wherein the cholesteric liquid crystal reflects near-infrared light having a wavelength band between 800 nm and 1000 nm with respect to front incident light parallel to a spiral axis of a liquid crystal molecule.

8. The display device of claim 1, wherein the cholesteric liquid crystal is oriented in a random direction.

9. The display device of claim 1, wherein the bank layer includes a matrix, and the matrix comprises a matrix resin for dispersing the cholesteric liquid crystal.

10. The display device of claim 9, wherein the cholesteric liquid crystal is oriented within a droplet dispersed in the matrix resin.

11. The display device of claim 1, wherein the cholesteric liquid crystal is transparent in a front direction and is red in a viewing angle direction.

12. The display device of claim 1,
wherein the light emitting diode comprises:
a first electrode disposed on the substrate;
a second electrode facing the first electrode; and
an emissive layer disposed between the first electrode and the second electrode, and
wherein each of the emissive layer and the second electrode is disposed to extend along an upper surface of the bank layer.

13. The display device of claim 12, wherein the bank layer further comprises a second side facing the first side, and wherein the second side of the bank layer has a cross-section that is inclined outwardly.

14. The display device of claim 13, wherein each of the emissive layer and the second electrode extends along the cross-section of the second side of the bank layer that is inclined outwardly.

15. The display device of claim 14, wherein the second side of the bank layer extends further toward a surface of the substrate compared to the first side of the bank layer.

16. The display device of claim 14, wherein the second side of the bank layer has an inclination angle greater than an inclination angle of the first side of the bank layer.

17. The display device of claim 12, wherein the first electrode is a transmissive electrode and the second electrode is a reflective electrode.

18. The display device of claim 1, wherein the display device further comprises a color control pattern disposed to correspond to the emission area between the substrate and the light emitting diode.

19. The display device of claim 1, wherein the display device further comprises a driving thin film transistor disposed on the substrate and connected to the light emitting diode.

20. The display device of claim 19, wherein the driving thin film transistor comprises an oxide semiconductor.
